(19) United States
(12) Patent Application Publication
(10) Pub. No.: US 2012/0013373 A1
(43) Pub. Date: Jan. 19, 2012

(54) SEMICONDUCTOR DEVICE, CIRCUIT CORRECTION METHOD, DESIGN SUPPORT DEVICE, AND RECORDING MEDIUM STORING DESIGN SUPPORT PROGRAM

(75) Inventor: Yuichi Nakamura, Tokyo (JP)

(73) Assignee: NEC CORPORATION, Tokyo (JP)

(21) Appl. No.: 13/203,197

(22) PCT Filed: Feb. 9, 2010
(86) PCT No.: PCT/JP2010/000794

§ 371 Date: Aug. 24, 2011

(30) Foreign Application Priority Data
Mar. 5, 2009 (JP) 2009-051880

(51) Int. Cl. H03L 7/00; G06F 9/45

(52) U.S. Cl. 327/141; 716/103

(57) ABSTRACT

There has been a problem in a conventional semiconductor device that a great deal of time is needed for a returning process associated with circuit correction. A semiconductor device according to the present invention includes a plurality of trigger signal driving elements (FFa and FFb) that synchronize with a trigger signal and operate, trigger wiring lines (CW0 to CW3) that distribute the trigger signal to the plurality of trigger signal driving elements, an additional trigger wiring line (CWb) that is provided by branching from the trigger wiring lines (CW0 to CW3), and an additional supply element (30) that is supplied with the trigger signal via the additional trigger wiring line (CWb) and separated from the plurality of trigger signal driving elements.

### TECHNICAL FIELD

The present invention relates to a semiconductor device, a circuit correction method, a design support device, and a design support program, and especially to a semiconductor device that includes a clock wiring line for distributing a clock signal to a trigger signal driving element, a circuit correction method of the semiconductor device, a design support device, and a design support program.

### BACKGROUND ART

In the design of a semiconductor, circuit correction on a function or performance may occur by a failure or an improvement of the circuit. It is not especially a problem when these circuit correction occur in the initial stage of design, however when the circuit correction occurs at a stage when the design of the semiconductor device advances (for example, at a stage when layout design is completed), a large returning process arises in the design process for the correction. Accordingly, when correcting the circuit which has completed its layout, the failure cannot be improved while maintaining the existing layout, and relayout is often required. Thus, an example of a design method to reduce the time taken for the returning process of design is disclosed in PTL 1.

In PTL 1, a cut is formed in the circuit beforehand, and the circuit correction is performed by the unit of the division. Then, a correction process can be performed only to the unit of division which requires the circuit correction while maintaining current design information (for example, layout information) of the unit of division which does not require correction. That is, in PTL 1, the time taken for the returning process is reduced by minimizing the region to perform relayout.

Further, in a semiconductor device in recent years, logical circuits using a flip-flop etc. which are driven according to clock signals are often used. In the semiconductor device, an error is generated in arrival time of clock signals among a plurality of flip-flops by parasitic capacitance of a clock wiring line which transmits the clock signals. Therefore, in the design of the logical circuit, an amount of delay of the arrival time of the clock signal and a difference in the arrival time of the trigger signals between trigger signal driving elements, which are connected to each other, are estimated in advance, and timing design is performed to avoid the failure resulting from the propagation delay of the clock signal. By this timing design, the logical circuit avoids the failure resulting from the propagation delay of the trigger signal. Note that the clock signal is widely included in the trigger signal, and the trigger signal includes a set signal, a reset signal, a request signal in asynchronous communication, an acknowledgement signal, etc. other than the clock signal. Additionally, the flip-flop is widely included in the trigger signal driving element, and the trigger driving element includes a latch, a memory, etc. other than the flip-flop. Further, the timing design is performed also to a data signal transmitted and received between the plurality of flip-flops.

In the semiconductor device using such logical circuit, when a flip-flop is added after completing the layout, it is required to perform timing design of the clock signals again. This is because that by the added flip-flop (for example, an additional flip-flop) and an additional clock wiring line, which supplies the clock signal to the added flip-flop, to the existing clock wiring line, the parasitic capacitance of the existing clock wiring line changes and this change causes the amount of clock signal to change. Accordingly, PTL 2 discloses a method to correspond to the change in the parasitic capacitance of the existing clock wiring line only by adjusting the clock wiring line, and eliminate the returning process as much as possible.

### CITATION LIST

### Patent Literature

PTL 1: Japanese Unexamined Patent Application Publication No. 11-250121
PTL 2: Japanese Unexamined Patent Application Publication No. 8-50604

### SUMMARY OF INVENTION

### Technical Problem

As mentioned above, when adding the flip-flop or the like after layout or design of the clock wiring line are completed, the returning process is generated for additional timing design and relayout. The time required for this returning process is huge, and thus a problem of largely increasing the design period arises. However, the design methods disclosed in PTL 1 and 2 cannot address this problem of increase in the design period.

More specifically, this is because that even by the design method disclosed in PTL 1, when the flip-flop is added, the timing design and relayout must be performed for the unit of division. Even when correcting only a part of the chip in the returning process, this returning process requires much time. Therefore, there is a problem in the design method disclosed in PTL 1 that the time of returning process cannot be sufficiently reduced.

Moreover, when the flip-flop is added using the design method disclosed in PTL 2, there is a problem that the arrival time of the clock signal for the additional flip-flop cannot be appropriately specified only by adjusting the clock wiring line, and the failure cannot he solved enough. When such a problem is generated, even in PTL 2, it is required to perform redesign from the initial stage for appropriate timing design and layout, and much time is required for the returning process. That is, also in the design method disclosed in PTL 2, there is a problem that the time of the returning process cannot be sufficiently reduced.

### Solution to Problem

An aspect of a semiconductor device according to the present invention includes a plurality of trigger signal driving elements that synchronize with a trigger signal and operate, a trigger wiring line that distributes the trigger signal to the plurality of trigger signal driving elements, an additional trigger wiring line that is provided by branching from the trigger wiring line, and an additional supply element that is supplied with the trigger signal via the additional trigger wiring line, and separated from the plurality of trigger signal driving elements.

A circuit correction method of a semiconductor device according to the present invention is a circuit correction method of the semiconductor device including a trigger wiring line that transmits a trigger signal, and a plurality of trigger signal driving elements that operate according to the trigger signal, in which the circuit correction method includes previously providing an additional supply element that is connected to the trigger wiring line via an additional trigger wiring line and also not connected to any of the plurality of trigger driving elements, searching for a correcting element that is to be corrected among the plurality of trigger signal driving elements, and connecting the correcting element and the additional supply element.

An aspect of a design support device according to the present invention is a design support device that, in a design process of a semiconductor device, places an additional supply element and an additional trigger wiring line for connecting the additional supply element and a trigger wiring line to the trigger wiring line for distributing a trigger signal to a trigger signal driving element, in which the design support device includes an additional supply element conditioning means that generates additional supply element statistical information indicating a number of the additional supply element for each of the constraint according to a number of the additional supply element and the constraint of the additional supply element, a branch position determining means that extracts information of the trigger wiring line from a first netlist describing connection information of a circuit including the plurality of trigger driving elements, and determines a position to place the additional supply element included in the additional supply element statistical information according to an extracted number of branch stage of the trigger wiring line, and outputs branch position information describing position information of the additional supply element, and a trigger wiring correction means that adds the connection information of the additional supply element and the additional trigger wiring line to the first netlist according to the branch position information and generates a second netlist.

An aspect of a design support device according to the present invention is a design support device that connects an additional supply element connected to a trigger signal driving element for operating according to a trigger signal included in a first netlist generated after completing a layout via a trigger wiring line and an additional trigger wiring line for transmitting the trigger signal, and also not connected to the trigger signal driving element, in which the design support device includes a correcting element searching means that searches for the trigger signal driving element positioned to both ends of an element adding node, which is to be corrected, from the first netlist, and registers the searched trigger signal driving element as a correcting element, a clock supplier analysis means that analyzes a number of branch stage of the trigger wiring line connected to the correcting element, and outputs clock supplier analysis information indicating the analyzed number of branch stage, an addition target determining means that searches for the additional supply element connected, to the trigger wiring line including the number of branch stage matching or close to the trigger wiring line for supplying the trigger signal to the correcting element according to the clock supplier analysis information, and determines the searched additional supply element as the additional supply element to be added, and a circuit correction means that generates a second netlist, in which the additional supply element determined by the addition target determining means is connected to the trigger signal driving element.

An aspect of a design support program according to the present invention is a design support system that is executed by a calculation device and in a design process of a semiconductor device, places an additional supply element and an additional trigger wiring line for connecting the additional supply element and a trigger wiring line to the trigger wiring line for distributing a trigger signal to a trigger signal driving element, in which the design support program includes an additional supply element conditioning means that reads additional supply element number information indicating a number of the additional supply element and additional supply element constraint information indicating a constraint of the additional supply element from a memory and stores additional supply element statistical information indicating the number of additional supply element for each of the constraint to the memory, a branching position determining means that reads a first netlist describing connection information of a circuit including the plurality of trigger driving elements from the memory, extracts information of the trigger wiring line from the first netlist, determines a position to place the additional supply element included in the additional supply element statistical information according to an extracted number of branch stage of the trigger wiring line, and stores branch position information describing position information of the additional supply element to the memory, and a trigger wiring correction means that adds the connection information of the additional supply element and the additional trigger wiring line to the first netlist according to the branch position information read from the memory, generates a second netlist, and stores the second netlist to the memory.

An aspect of a design support program according to the present invention is a design support program that is executed by a design support program calculation device, and connects an additional supply element connected to a trigger signal driving element for operating according to a trigger signal included in a first netlist generated after completing a layout via a trigger wiring line and an additional trigger wiring line for transmitting the trigger signal, and also not connected to the trigger signal driving element, in which the design support program includes a correcting element searching means that reads the first netlist from a memory, searches for the trigger signal driving element positioned to both ends of an element adding node, which is to be corrected, from the first netlist, and stores correcting element analysis information indicating the searched trigger signal driving element to the memory, a clock supplier analysis means that reads the first netlist and the correcting element analysis information form the memory, analyzes a number of branch stage of the trigger wiring line connected to the correcting element, and stores clock supplier analysis information indicating the analyzed number of branch stage, an addition target determining means that reads the clock supplier analysis information from the memory, searches for the additional supply element connected to the trigger wiring line including the number of branch stage matching or close to the trigger wiring line for supplying the trigger signal to the correcting element, and determines the searched additional supply element as the additional supply element to be added, and a circuit correction means that generates a second netlist, in which the additional supply element determined by the addition target determining means is connected to the trigger signal driving element, and stores the second netlist to the memory.

### Advantageous Effects of Invention

By the semiconductor device, the circuit correction method, the design support device, and the design support program according to the present invention, it is possible to reduce the time of returning process associated with the circuit correction.

### BRIEF DESCRIPTION OF DRAWINGS

FIG. 1 is a block diagram of a semiconductor device according to a first exemplary embodiment;

FIG. 2A is a circuit example of an additional supply element according to the first exemplary embodiment;

FIG. 2B is another circuit example of the additional supply element according to the first exemplary embodiment;

FIG. 2C is another circuit example of the additional supply element according to the first exemplary embodiment;

FIG. 3 is a block diagram of a semiconductor device, which is the semiconductor device performed with circuit correction;

FIG. 4 is a flowchart showing a circuit design procedure of a semiconductor device according to a second exemplary embodiment;

FIG. 5 is a block diagram of a design support device of the semiconductor device according to the second exemplary embodiment;

FIG. 6 is a flowchart showing an operation procedure of the design support device according to the second exemplary embodiment;

FIG. 7 is a flowchart showing a circuit correction procedure of the semiconductor device according to a third exemplary embodiment;

FIG. 8 is a block diagram of a design support device of the semiconductor device according to the third exemplary embodiment;

FIG. 9 is a flowchart showing an operation procedure of the design support device according to the third exemplary embodiment;

FIG. 10 is a block diagram showing an example of the semiconductor device performed with circuit correction by the design support device according to the third exemplary embodiment; and

FIG. 11 is a block diagram showing another example of the semiconductor device performed with circuit correction by the design support device according to the third exemplary embodiment.

### DESCRIPTION OF EMBODIMENTS

### First Exemplary Embodiment

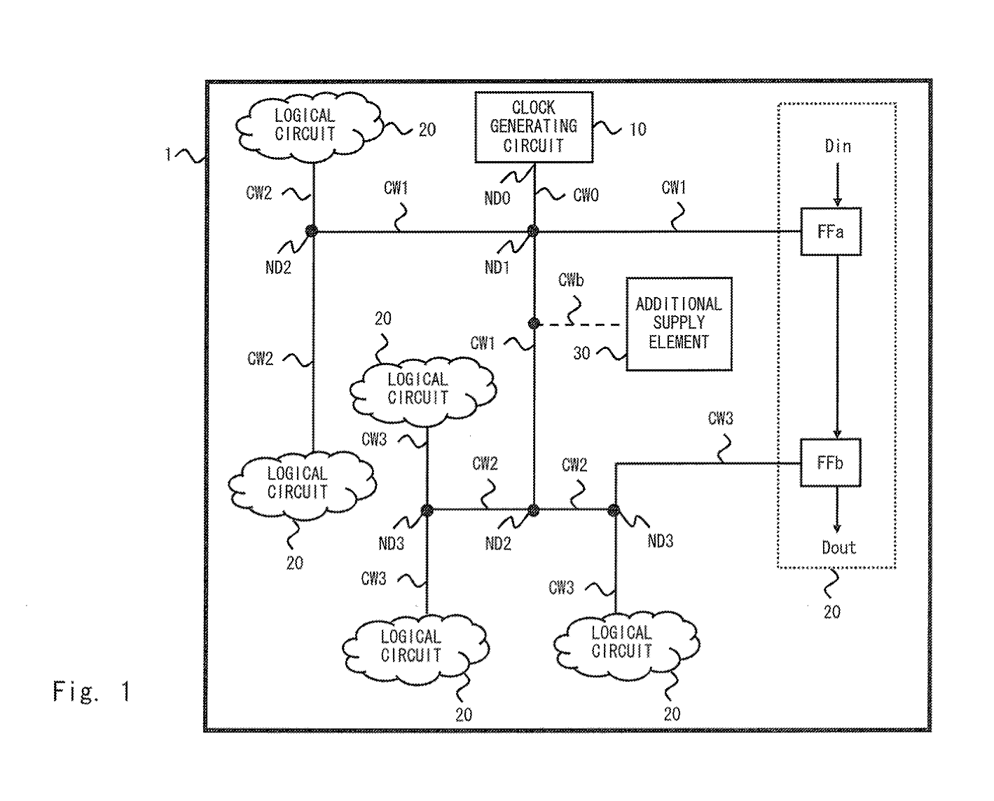

Hereinafter, exemplary embodiments of the invention are described with reference to the drawings. First, a block diagram of a semiconductor device 1 according to a first exemplary embodiment is shown in FIG. 1. As shown in FIG. 1, the semiconductor device includes a clock generating circuit 10, a logical circuit 20, an additional supply element 30, trigger wiring lines CW0 to CW3, and an additional trigger wiring line CWb. Further, the semiconductor device 1 includes a plurality of logical circuits 20.

The clock generating circuit 10 distributes a trigger signal (for example, a clock signal) to the logical circuit 20 via the trigger wiring lines (for example, clock wiring lines) CW0 to CW3. The logical circuit 20 includes a plurality of trigger signal driving elements which operate according to the trigger signal supplied via the trigger wiring line. In FIG. 1, one of the logical circuits 20 includes flip-flop circuits FFa and FFb. Here, in this exemplary embodiment, the flip-flop circuit is used as an example of the trigger signal driving element. Further, a clock signal is used as the trigger signal, and the trigger wiring line is referred to as a clock wiring line. However, the trigger signal driving element should only be a circuit element which operates according to the trigger signal, and there are a latch circuit and a memory circuit other than the flip-flop circuit. Furthermore, the trigger signal includes a set signal, a reset signal, a request signal in asynchronous communication, an acknowledgement signal, etc. other than the clock signal.

Moreover, in FIG. 1, the number is added after the code CW. This number indicates the number of branch stages of the clock wiring line, and in this exemplary embodiment, the clock wiring line CW0, which is connected to an output terminal of the clock generating circuit 10, shall be a reference. Note that a starting point of the number of branch stage of the clock wiring line can be arbitrarily specified.

Further, in FIG. 1, branch points of the clock wiring lines are denoted by ND0 to ND3. Although the numbers are added after the code ND for the branch points, the numbers indicate the number of branch stages of the clock wiring line. In this exemplary embodiment, the output terminal of the clock generating circuit 10 shall be the starting point of the branch point. Note that the starting point of the number of branch points can be arbitrarily specified.

Additionally, in the semiconductor device 1 according to this exemplary embodiment, a constraint (for example, a skew value) is specified for each clock wiring line CW0 to CW3. That is, a fixed skew value is specified to the clock wiring line CW0 for the clock wiring line CW1. The skew value of the clock wiring line CW2 is specified to have a value which is constant to the clock wiring line CW0 and different from that of the clock wiring line CW1. The skew value of the clock wiring line CW3 is specified to have a value which is constant to the clock wiring line CW0 and different from those of the clock wiring lines CW1 and CW2.

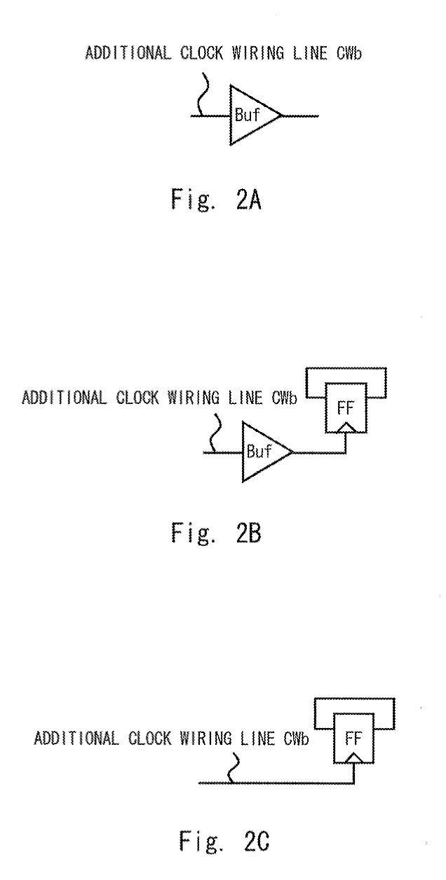

The additional supply element 30 is supplied with a clock signal via an additional trigger wiring line (for example, an additional clock wiring line), and separated from the plurality of flip-flop circuits. Then, it is connected to the plurality of flip-flop circuits in the circuit correction. Examples of this additional supply element 30 are shown in FIG. 2A to FIG. 2C. The additional trigger wiring CWb is a wiring line provided by branching from the clock wiring line, and the same constraint (for example, the skew value) as the clock wiring line of a branch source is specified. Further, a constraint (for example, a skew value) in consideration of next usage state is previously specified to the additional supply element 30, which is placed according to the constraint. That is, the additional supply element 30 is placed at a place where the constraint of the additional supply element and the constraints of the clock wiring lines CW0 to CW3 match.

In the example shown in FIG. 2A, a buffer BUF is used for the additional supply element. As for the buffer BUF, an input terminal is connected to the clock wiring line via the additional clock wiring line CWb, and an output terminal will be an open end when it is not used for the circuit correction. In the example shown in FIG. 2B, a buffer BUF and a flip-flop circuit FF are used as the additional supply elements. As for the buffer BUF, an input terminal is connected to the clock wiring line via the additional clock wiring line CWb, and an output terminal is connected to a clock input terminal of the flip-flop circuit FF. In the flip-flop FF, the input terminal and the output terminal are connected to each other in the state not used for the circuit correction. In the example shown in FIG. 2C, a flip-flop circuit FF is used as the additional supply element. In the flip-flop circuit, an input terminal and an output terminal are connected to each other in the state not used for the circuit correction, and a clock input terminal is connected to the clock wiring line via the additional clock wiring line CWb.

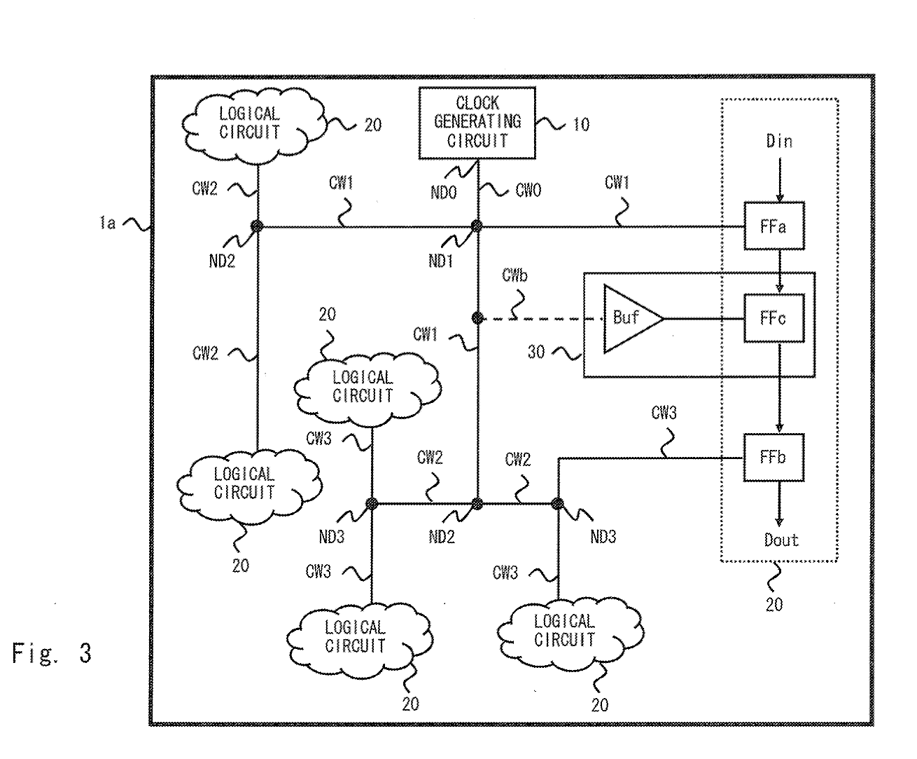

The semiconductor device 1 according to this exemplary embodiment uses the additional supply element 30 in the case of performing circuit correction. Then, a block diagram of a semiconductor device 1a, which is the semiconductor device 1 shown in FIG. 1 corrected using the circuit correction method according to this exemplary embodiment, is shown in FIG. 3. As shown in FIG. 3, in the circuit correction method according to this exemplary embodiment, a flip-flop circuit FFc included in the additional supply device is connected between the flip-flop circuits FFa and FFb, which have been originally used in the logical circuit 20. The flip-flop circuit FFc is supplied with the clock signal via the additional clock wiring line CWb, which is provided by branching from the clock wiring line CW1, and the buffer BUF.

As described so far, the circuit correction of the semiconductor device according to this exemplary embodiment is a circuit correction method for the semiconductor device including the clock wiring line which transmits the clock signal, and the plurality of flip-flop circuits which operate according to the clock signal, and the additional supply element 30 is previously provided, which is connected to the clock wiring lines CW0 to CW3 via the additional clock wiring line, and also not connected to any of the plurality of flip-flop circuits, searches for a correcting element (in the example shown in FIG. 3, the flip-flop circuits FFa and FFb) to be corrected among the plurality of flip-flop circuits, and connects the flip-flop circuits FFa and FFb to the additional supply element 30.

As described above, in the semiconductor device according to this exemplary embodiment, the additional clock wiring line and the additional supply element 30 are embedded beforehand, and the additional supply element 30 is used in subsequent circuit correction. At this time, the skew values of the clock wiring lines CW0 to CW3 are specified in the initial stage of the design including the parasitic capacitance resulting from the additional supply element 30 and the additional clock wiring line CWb. Therefore, even when a circuit element is added which receives the clock signal from the clock wiring lines CW0 to CW3 in the circuit correction, the value of the parasitic capacitance of the clock wiring lines CW0 to CW3 can be kept constant by using the additional supply element. In other words, the skew values of the clock wiring lines CW0 to CW3 are not fluctuated by the circuit correction, as long as the additional supply element is used. Therefore, in the semiconductor device according to this exemplary embodiment, even when the additional supply element 30 and the additional clock wiring line CWb are used in the circuit correction process, it is not necessary to perform calculation (timing design) of the skew value of the clock signal again. That is, in the semiconductor device according to this exemplary embodiment, the time taken for the returning process associated with the circuit correction can be reduced.

Moreover, in general, adding an element not used for the semiconductor device is not performed as it causes an increase in the chip area. However, the additional supply element 30 according to this exemplary embodiment is a small circuit of one or two buffer circuit or flip-flop circuit FFa etc, and even when the additional supply element 30 is added, there is almost no increase in the chip area. In the miniaturized process of recent years, the disadvantage from the increase in the cost and time caused by the returning process associated with the circuit correction tends to be larger than the disadvantage of such small increase in the chip area. For example, when a circuit element not originally existing in the semiconductor device is added later, reticles corresponding to a lower layer of a wafer (circuit formation layer) must be corrected, and in such case, all reticles must be remanufactured. In the semiconductor element which is miniaturized in recent years, much time and cost is required to remanufacture all the reticles. However, in the semiconductor device according to this exemplary embodiment, only the reticles corresponding to the circuit wiring layer may be remanufactured. Therefore, in the semiconductor device according to this exemplary embodiment, it is possible to suppress the cost and time of the reticle manufacture associated with the circuit correction. In other words, in the miniaturized process of recent years, an effect of reducing design time and suppressing the cost by the present invention is distinguished.

A designer can arbitrarily place the additional supply element 30 and the additional clock wiring line CWb. However, in the design of the semiconductor device of recent years, it is common to automate complicated processes using the design support device, such as a computer. Then, the following second exemplary embodiment explains the design procedure of the semiconductor device 1 using the design support device, and the third exemplary embodiment explains the circuit correction method using the design support device.

### Second Exemplary Embodiment

In the second exemplary embodiment, the design procedure of the semiconductor device 1 explained in the first exemplary embodiment is explained. Then, a flowchart of the configuration procedure of the semiconductor device 1 is shown in FIG. 3. As shown in FIG. 3, in the design of the semiconductor device 1, circuit design is performed first (step S1). In this circuit design, the design of the circuit is performed according to the function and specification of the semiconductor device 1. In the design of the step SI, the design using HDL (Hardware Description Language) such as Velirog (this design is referred to as RTL (Register Transfer Level) is performed. Next, logic synthesis of the circuit designed in the step S1 is performed, and a first netlist for design verification is generated (step S2). The logic synthesis process generates the first netlist for design verification M1 which describes specific circuit configuration (including connections between elements) according to the description created by the design performed in the step S1.

Next, the additional clock wiring line CWb and the additional supply element 30 are added to the first netlist for design verification M1, and a second netlist for design verification M2 is generated (step S3). Although the additional supply element 30 and the additional clock wiring line CWb of the semiconductor device 1 are added to the circuit in this step S3, the detailed procedure of the step S3 is described later. Further, although the additional clock wiring line CWb and the additional supply element 30 are added in the step S3 in this exemplary embodiment, the process to add the additional clock wiring line CWb and the additional supply element 30 may be performed at any step as long as it is at a stage before generating a netlist for reticles of the semiconductor device 1 (the netlist to be a reference of the reticles used in the manufacturing process). For example, the additional supply element 30 can be added in the circuit design of the step S1, or can be added to the circuit after performing a layout process, which is performed later.

Subsequently, a CTS (Clock Tree Synthesis) buffer is inserted to the second netlist for design verification M2 generated in the step S3 (step S4). The CTS buffer is a buffer inserted to the clock wiring lines CW0 to CW3, and adjusts the skew values of the clock wiring lines CW0 to CW3. Then, it is verified whether the adjustment of the skew value by the CTS buffer inserted in the step S4 is appropriately performed (steps S5 and S6). This verification is same as the timing verification, and the verification performed to the skew value of the clock signal is especially referred to as clock skew verification.

In the step S6, when the timing verification result is not appropriate (branch of NO in the step S6), the second netlist for design verification is corrected (step S7), and verification operation of the step 5 and the step 6 is performed again. On the other hand, in the step S6, when the timing verification result is appropriate (branch of YES in the step S6), a netlist for layout M3 is generated, which is the second netlist for design verification added with the information of the CTS buffer.

In the layout process, a layout pattern of the semiconductor device is generated according to the netlist for layout (step S8). The circuit layout and wiring length and wiring width connecting between the circuit elements are determined in this step S8. Subsequently, signal delay verification (back annotation) taking consideration of the parasitic resistance and parasitic capacitance of the wiring line extracted from the layout pattern of the step S8 is performed (step S9). In this back annotation, verification whether setup time and hold time of the flip-flop etc. satisfies the reference is performed. When the verification result of the back annotation is not appropriate (branch of NO in the step S10), the netlist for layout is corrected (step S11), and the relayout (step S8) and the back annotation (step S9) is performed again. On the other hand, when the verification result of the back annotation is appropriate (branch of YES in the step S10), a netlist for reticles M4 is generated according to the netlist for layout. Then, the semiconductor device 1 is manufactured according to the netlist for reticles.

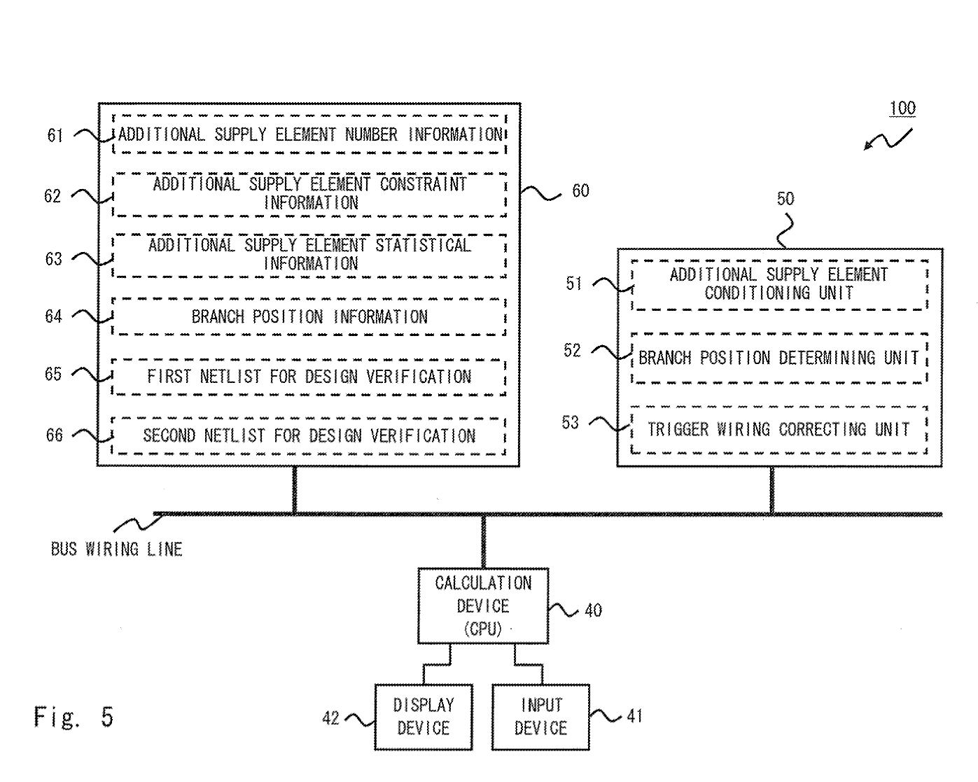

As mentioned above, in the second exemplary embodiment, the additional supply element 30 and the additional clock wiring line CWb are added in the step S3. At this time, in the second exemplary embodiment, the process of the step S3 is performed using a design support device 100. Thus, a block diagram of the design support device 100 is shown in FIG. 5. Note that the design support device 100 may be a computer or the like mounted with a design support program for executing the process of the step S3, or may be a device dedicated for performing the process of the step S3. Hereinafter, a computer or the like mounted with the design support program for performing the process of the step S3 is explained as an example of the design support device 100.

As shown in FIG. 5, the design support device 100 includes a calculation device (for example, CPU: Central Processing Unit) 40, an input device 41, a display device 42, a program memory 50, and a database memory 60. While performing the process according to various programs read from the program memory 50 and various information read from the database memory 60, the calculation device 40 stores the information generated from the process to the database memory 60. The calculation device 40 is connected to the program memory 50 and the database memory 60 via a bus wiring line. The input device 41 is the one which gives directions of the operation to the calculation device 40. The display device 42 displays an interface screen of the program executed in the calculation device 40.

A design support program, which places the additional supply element 30 and the additional clock wiring line for connecting between the additional supply element 30 and the clock wiring line to the clock wiring line which distributes the clock signal to the flip-flop circuits in the design process (for example, the abovementioned step S3) of the semiconductor device, is stored to the program memory 50. The design support program includes an additional supply element conditioning unit 51, a branch position determining unit 52, and a trigger wiring correcting unit 53. As for the design support program, these three units may be implemented as one program, or may be implemented as individual programs.

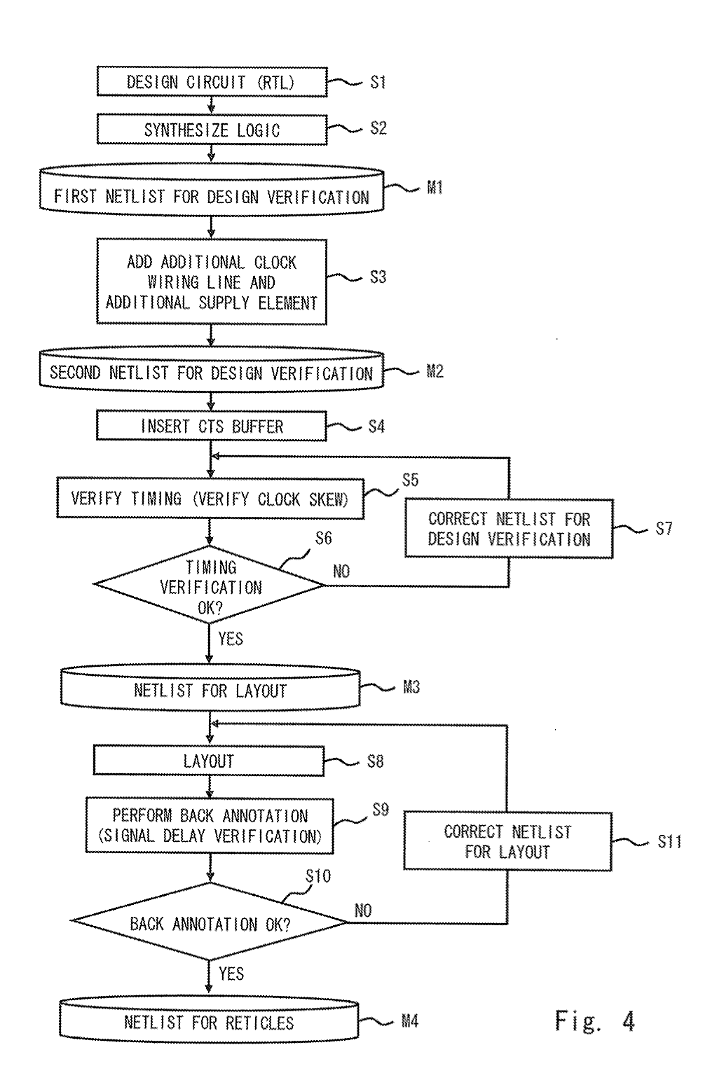

Further, the database memory 60 stores additional supply element number information 61, additional supply element constraint information 62, additional supply element statistical information 63, branch position information 64, a first netlist for design verification 65, and a second netlist for design verification 66. The additional supply element number information 61 and the additional supply element constraint information 62 is information input by a designer via the input device 41 and the calculation device 40. The additional supply element statistical information 63 is information generated by the additional supply element conditioning unit 51. The branch position information 64 is information generated by the branch position determining unit 52. The first netlist for design verification 65 is a netlist generated in the step S2 of FIG. 4, and is referred to as a first netlist depending on the case in the explanation of the design support device 100 and the design support program executed in the design support device 100. The second netlist for design verification 66 is a netlist generated by the trigger wiring correcting unit 53, and is referred to as a second netlist depending on the case in the explanation of the design support device 100 and the design support program executed in the design support device 100.

The additional supply element conditioning unit 51 reads the additional supply element number information 61 indicating the number of the additional supply elements and the additional supply element constraint information 62 indicating the constraint of the additional supply element from the database memory 60, and generates the additional supply element statistical information 63 indicating the number of the additional supply elements for each constraint. This additional supply element statistical information 63 is stored to a memory.

The branch position determining unit 52 reads the first netlist (for example, the first netlist for design verification 65) which describes the connection information of the circuits including the plurality of flip-flop circuits from the database memory 60, and extracts information of the clock wiring line from the first netlist for design verification 65. Then, the branch position determining unit 52 determines the position to place the additional supply element included in the additional supply element statistical information according to the extracted information of the number of branch stages of the clock wiring line. More specifically, the branch position determining unit 52 searches for the number of branch stages of the clock wiring line which satisfies the constraint included in the statistical information, and determines the position of the clock wiring line corresponding to the searched number of branch stages as the additional supply element and the additional trigger wiring line. Then, the branch position determining unit 52 stores the branch position information 64 describing the position information of the additional supply element 30 to the database memory. In this exemplary embodiment, the constraints are specified to the clock wiring line by each number of branch stages. Therefore, the branch position determining unit 52 determines the position to add the additional supply element 30 according to the consistency between the constraint specified to the clock wiring line and the constraint specified to the additional supply element 30. The details of this determination process are described later.

The trigger wiring correcting unit 51 adds the connection information of the additional supply element 30 and the additional clock wiring line CWb to the first netlist for design verification 65 according to the branch position information read from the database memory 60, and generates the second netlist (for example, the second netlist for design verification 66). Then, the trigger wiring correcting unit 51 stores the second netlist for design verification to the database memory 60.

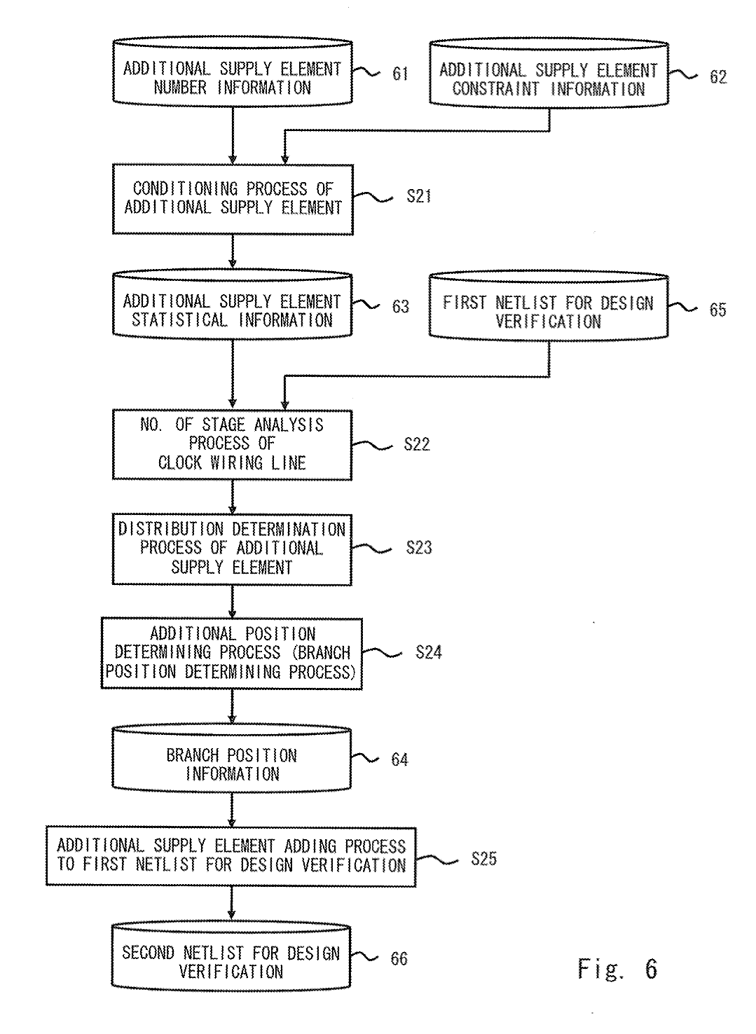

Next, the procedure by the design support device 100 is explained. A flowchart of the procedure by the design support device 100 is shown in FIG. 6. In the design support device 100, the additional supply element conditioning unit 51 is executed in the calculation device 40. The additional supply element conditioning unit 51 reads the additional supply element number information 61 and the additional supply element constraint information 62, and generates the additional supply element statistical information 63 (step S21). The additional supply element statistical information 63 includes information of, for example, 30 the additional supply elements 30 with the constraints (for example the skew values) of 100 ps, and 100 additional supply elements with the skew values of 50 ps. Specifically, the additional supply element statistical information 63 includes statistical information of the additional supply elements having the same constraint.

Next, in the design support device 100, the branch position determining unit 52 is executed in the calculation device 40. The branch position determining unit 52 firstly reads the additional supply element statistical information 63 and the first netlist for design verification 65. Then, the branch position determining unit 52 analyzes the number of branch stage of the existing clock wiring lines from the first netlist for design verification 65 (step S22). More specifically, in the example of this exemplary embodiment, a calculation is performed in which with the clock wiring line CW0 as a reference, how many branch points ND the calculation target clock wiring line passes through from the clock wiring line CW0.

Next, the branch position determining unit 52 determines distribution of the additional supply element (step S23). Specifically, the additional supply element having the constraint which can be accepted by the constraint specified to the clock wiring line for each number of branch stages is distributed to the clock wiring line according to the information included in the additional supply element statistical information 63. An example of the distribution method is explained here.

First, the constraints of the additional supply element include a maximum clock skew value Skew_max and a minimum clock skew value Skew_min. Then, a coefficient δ is defined by a formula (1).

δ=(Skew_max−Skew_min) (1)

Further, a coefficient θ is calculated in a formula (2). Note that in the formula (2), BRCH is the largest value (that is, the total number of branch stages of the clock wiring lines) among the number of branch stages of the clock wiring lines.

θ=δ/BRCH (2)

Then, the additional supply elements are categorized using formulas (31) to (3n) according to the constraints of the additional supply elements. Note that in the formulas (31) to (3n), n is an integer indicating the number of branch stages of the clock wiring line. Moreover, λ is the skew value specified to the clock wiring line, and is a different value for each number of stages of the clock wiring line (for example, the clock skew value of the clock wiring line including n number of branch stages is represented by λn, for example).

Skew_min<=λ1<=Skew_min+θ (31)

Skew_min<=λ2<=Skew_min+2θ (32)

Skew_min<=λ3<=Skew_min+θ (33)

Skew_min<=λn<=Skew_min+nθ (3n)

The case is explained of supplying the additional supply element 30, in which 100 ps as the maximum clock skew value Skew_max and 40 ps as the minimum skew value Skew_min are specified, to the clock wiring line including three branch stages. In this case, δ=60 ps and θ=20 ps. At this time, when λ1 to λ3 are respectively specified as 30 ps, 60 ps, and 90 ps, the formula (32) is the one that is the smallest number of stages and also satisfies the condition represented by the formula. Therefore, the clock wiring line CW2 including two branch stages is determined as the branch target of this additional supply element.

Then, the branch position determining unit 52 outputs the position of the additional clock wiring line CWb and the information of the additional supply elements which are determined by the process of the step S23 as the branch position information 64 (step S24). Next, the trigger wiring correcting unit 53 adds the element information and the connection information of the additional supply element 30 and the additional clock wiring line CWb to the first netlist for design verification 65 according to the branch position information, and generates the second netlist for design verification 66 (step S25).

From the above explanation, the design support device 100 according to the second exemplary embodiment can appropriately insert the plurality of additional supply elements and clock wiring line by inputting for each additional supply element the constraint of the additional supply element 30, is to be added. This design support device 100 can reduce the design time as the number of additional supply elements to be added increases. Specifically, when the designer searches for the clock wiring line to add by himself and provides the additional supply elements there, the search requires time when the clock wiring lines to be added are enormous. On the other hand, the design support device 100 according to this exemplary embodiment can instantly evaluate the clock wiring line having the constraint which satisfies the constraint of the additional supply element by inputting the constraint of the additional supply element 30 to be added for each additional supply element, and automatically provide the additional supply elements to the clock wiring line. In summary, by using the design support device 10, it is possible to reduce the time (the time taken for the step S3 of FIG. 4) taken for the insertion process of the additional supply element.

### Third Exemplary Embodiment

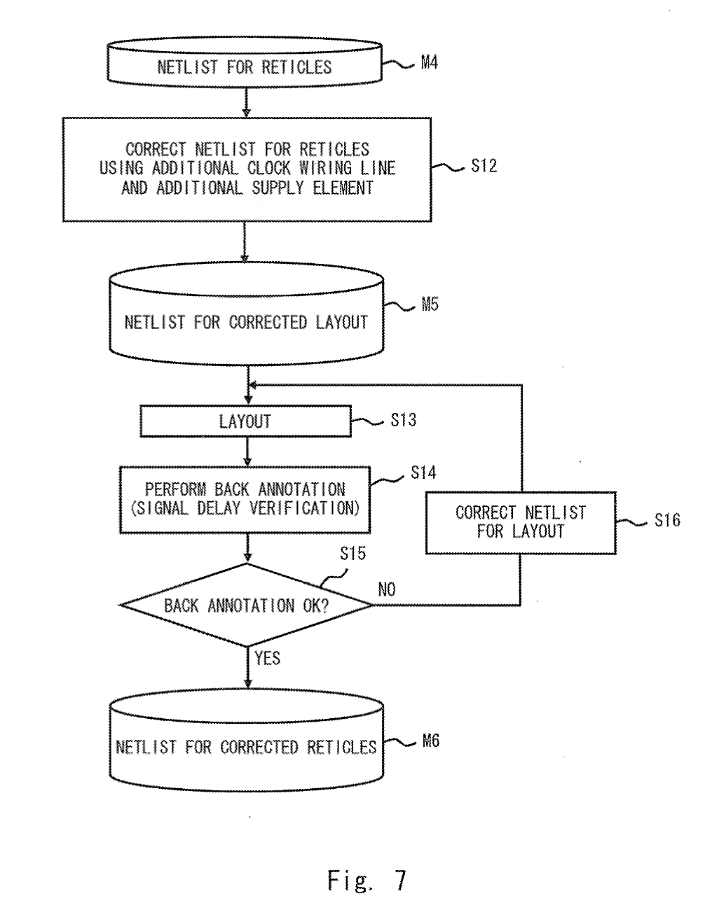

A third exemplary embodiment explains the circuit correction procedure of semiconductor device 1 explained in the first exemplary embodiment. Then, a flowchart of the circuit correction procedure of the semiconductor device 1 is shown in FIG. 7. As shown in FIG. 7, in the circuit correction of the semiconductor device 1, the netlist for reticles M4 used in the manufacture of the semiconductor device 1 is read first. Then, the circuit correction using the additional clock wiring line CWb and the additional supply element 30 is performed to the netlist for reticles M4 (step S12). A netlist for corrected layout M5 is generated by the circuit correction of the step S12.

Then, in the circuit correction process, the layout and the back annotation process (the processes of the steps S13 to S16) is performed according to the netlist for corrected layout, and a netlist for corrected reticles M6 is generated. The processes of the steps S13 to S16 respectively correspond to the processes of the steps S8 to S11 explained in FIG. 4. After the circuit correction process, a semiconductor device 1a shown in FIG. 3, for example, is manufactured is manufactured.

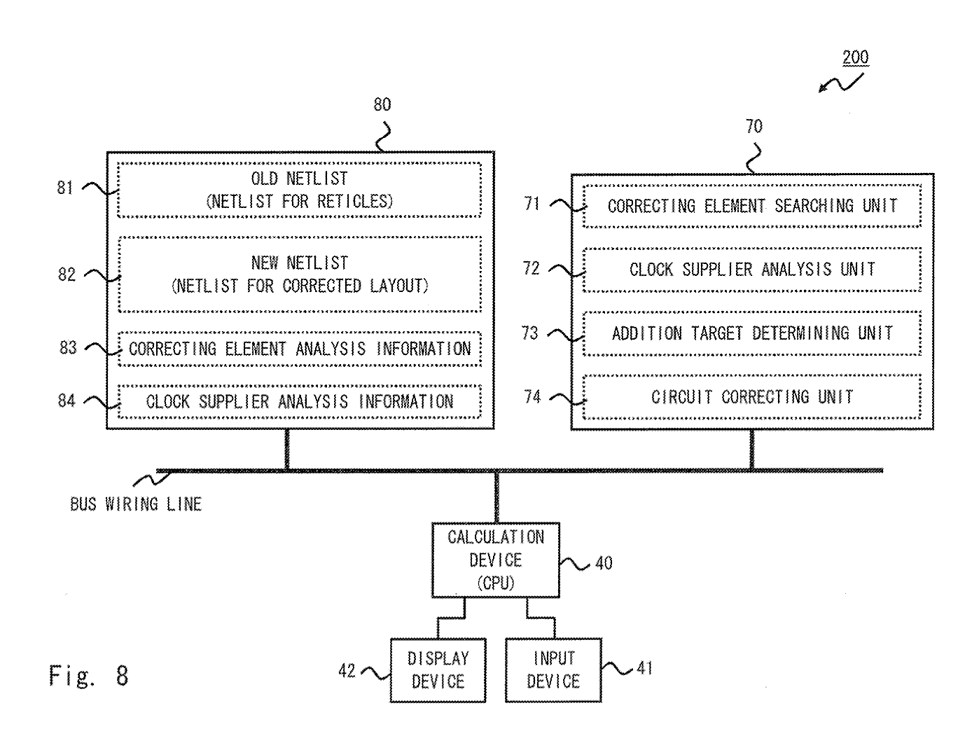

As mentioned above, in the third exemplary embodiment, the circuit correction using the additional supply element 30 and the additional clock wiring line CWb is performed in the step S12. At this time, in the third exemplary embodiment, the process of the step S12 is performed by a design support device 200. Then, a block diagram of the design support device 200 is shown in FIG. 8. Note that the design support device 200 may be a computer or the like mounted with a design support program for executing the process of the step S12, or may be a device dedicated for performing the process of the step S12. Hereinafter, a computer or the like mounted with the design support program for performing the process of the step S12 is explained as an example of the design support device 200.

As shown in FIG. 8, the design support device 200 includes a calculation device (for example, CPU: Central Processing Unit) 40, an input device 41, a display device 42, a program memory 70, and a database memory 80. While performing the process according to various programs read from the program memory 70 and various information read from the database memory 80, the calculation device 40 stores the information generated from the process to the database memory 80 calculation device 40 is connected to the program memory 70 and the database memory 80 via a bus wiring line. The input device 41 is the one which gives directions to the calculation device 40. The display device 42 displays an interface screen of the program executed in the calculation device 40.

The program memory 70 stores a design support program which connects a flip-flop circuit operating according to a clock signal included in the first netlist (for example, the netlist for reticles M4) generated after completing the layout and the additional supply element 30 which is connected to the clock wiring line for transmitting the clock signal via the additional clock wiring line and also not connected to the flip-flop circuit. The design support program includes a correcting element searching unit 71, a clock source analysis unit 72, an addition target determining unit 73, and a circuit correcting unit 74. As for the design support program, these four units may be implemented as one program or may be implemented as individual programs.

Further, the database memory 80 stores a netlist for reticles 81, a netlist for corrected layout 82, correcting element analysis information 83, and clock source analysis information 84. The netlist for reticles 81 is generated in accordance with the design flow explained in FIG. 4. The netlist for corrected layout is a netlist finally output by the design support device 200, and is a base of the semiconductor device after circuit correction. The correcting element analysis information 83 is the information generated by the correcting element searching unit 71. The clock source analysis information 84 is information generated by the clock source analysis unit 72. Note that in the explanation of the design support device 200 and the design support program executed by the design support device 200, the netlist for reticles 81 is referred to as a first netlist depending on the case. Moreover, in the explanation of the design support device 200 and the design support program executed by the design support device 200, the netlist for reticles 82 is referred to as a second netlist depending on the case.

The correcting element searching unit 71 reads the netlist for reticles 81 from the database memory 80. Then, the correcting element searching unit 71 searches for the flip-flop circuits positioned to the both sides of an adding node (the flip-flop circuit hereinafter referred to as a correcting element), and stores the correcting element analysis information 83 indicating the position of the searched flip-flop circuit to the database memory 80.

The clock source analysis unit 72 reads the first netlist (for example, a netlist for reticles 81) and the correcting element analysis information 83 from the database memory 80. Then, the clock source analysis unit 72 analyzes the number of branch stages of the clock wiring line connected to the correcting element, and stores the clock source analysis information 84 indicating the analyzed number of branch stages to the database memory 80.

The addition target determining unit 73 reads the clock source analysis information 84 from the database memory 80, searches for the additional supply element having the number of branch stages which matches or similar to the clock wiring line that supplies the clock signal to the correcting element, and determines the searched additional supply element as the additional supply element to be added.

The circuit correcting unit 74 generates the second netlist (for example, the netlist for corrected layout), in which the additional supply element determined by the addition target determining unit 73 is connected to the flip-flop circuit, and stores the second netlist to the memory.

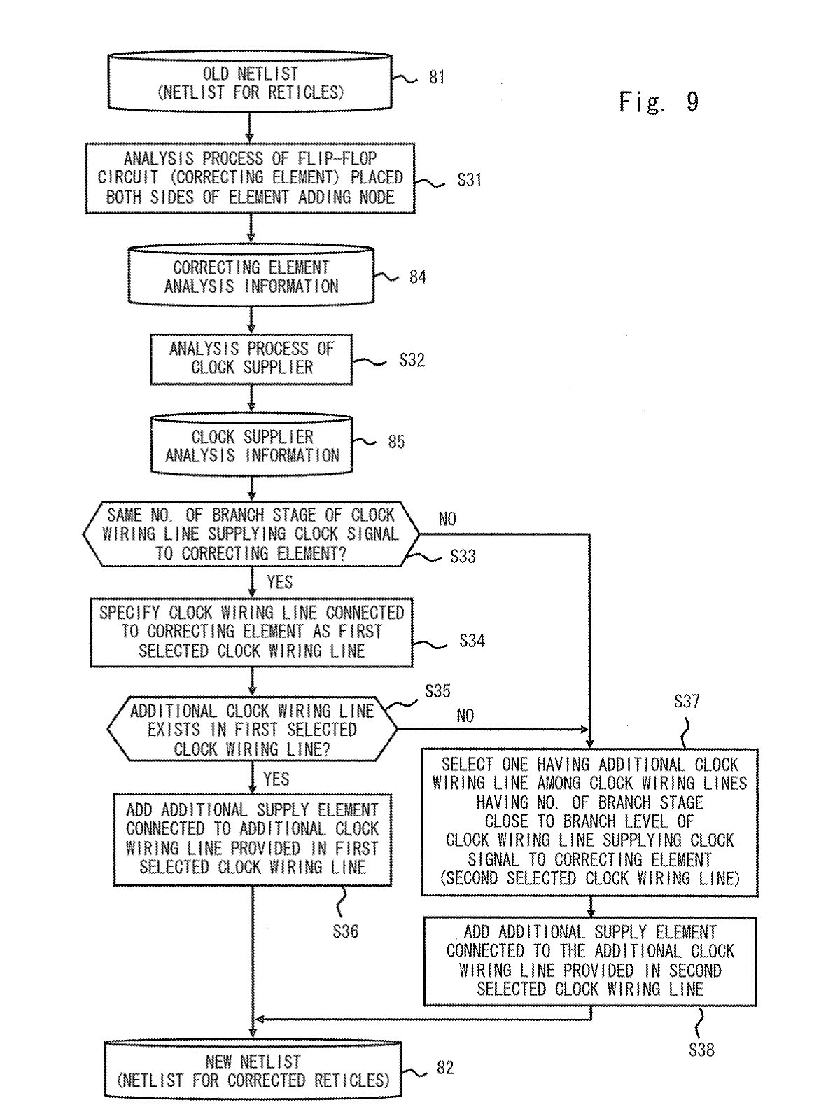

Next, the procedure by the design support device 200 is explained. A flowchart of the procedure by the design support device 200 is shown in FIG. 9. In the design support device 200, firstly the correcting element device searching unit 71 is executed in the calculation device 40. The correcting element searching unit 71 reads the netlist for reticles 81. Then, the correcting element searching unit 71 identifies the flip-flop circuits (these flip-flop circuits are referred to as the correcting elements) placed to the both ends of an element adding node to insert the additional supply element according to the circuit information described in the netlist for reticles 81 (step S31). That is, the correcting element includes at least two flip-flop circuits.

Then, the correcting element device searching unit 71 outputs the correcting element device analysis information 83 including the information of the identified correcting element.

Next, the design support device 200 executes the clock source analysis unit 72. The clock source analysis unit 72 analyzes the number of branch stages of the clock wiring line which supplies the clock signal to the correcting element based on the correcting element analysis information 83 and the netlist for reticles 81. In the step S32, for example, in the case in which two flip-flop circuits are included in the correcting element, an analysis is performed for the number of branch stages of the clock wiring line which supplies the clock signal to one of the flip-flop circuits, and the number of branch stages of the clock wiring line which supplies the clock signal to the other flip-flop circuit. Then, the clock source analysis unit 72 generates the clock source analysis information 84 which includes the number of branch stage information of the clock wiring line which supplies the clock signal to the correcting element obtained from the analysis.

Then, the design support device 200 executes the addition target determining unit 73. The addition target determining unit 73 firstly reads the clock source analysis information 84. Then, an evaluation is performed whether the number of branch stages of the clock wiring line which supplies the clock signal to the plurality of flip-flop circuits included in the correcting element is same among the plurality of flip-flop circuits (step S33). When it is evaluated that in the step S33 the clock signal is supplied from the clock wiring line having the same number of branch stages to the plurality of flip-flop circuits included in the correcting element (branch of YES in the step S33), the clock wiring line connected to the correcting element is specified as a first selected clock wiring line (step S34). Then, it is evaluated whether the additional clock wiring line exists in the first clock wiring line (step S35). When there is the additional clock wiring line in the first clock wiring line in the step S35 (branch of YES in the step S35), the additional supply element connected to the additional clock wiring line provided to the first selected clock wiring line is determined as an element to be added. Then, in response to the determination of the addition target determining unit 73, the circuit correcting unit 74 generates the second netlist (for example, netlist for corrected layout 82) including the connection information of the additional supply elements determined as an adding object, and the existing flip-flop circuit (step S36).

On the other hand, in the step S33, when it is evaluated that the clock signal is supplied from the clock wiring line having a different number of branch stages to the plurality of flip-flop circuits included in the correcting element (branch of NO in the step S33), and in the step S35, when there is no additional clock wiring line in the first clock wiring line (branch of NO in the step S35), a clock wiring line that is considered as optimal after the first selected clock wiring line selected in the step S34 is searched (step S37). In the process of S37, the addition target determining unit 73 searches for the clock wiring line having the number of branch stages close to the number of branch stages of the clock wiring line which supplies the clock signal to the correcting element, and detects the clock wiring line having the additional clock wiring line. Then, the addition target determining unit 73 selects the detected clock wiring line as the second selected clock wiring line. Next, the addition target determining unit 73 determines the one closest to the correcting element among the additional supply elements connected to the second selected clock wiring line as the additional supply element to be added. Specifically, the addition target determining unit 73 preferentially selects the additional supply element connected to the clock wiring line having the number of branch stages close to the clock wiring line which supplies the clock signal to the correcting element as the addition target. The circuit correcting unit 74 generates the second netlist (for example, the netlist for corrected layout 82), which is the connection information of the additional supply element determined according to the determination of the addition target determining unit 73 and the correcting element (step S38).

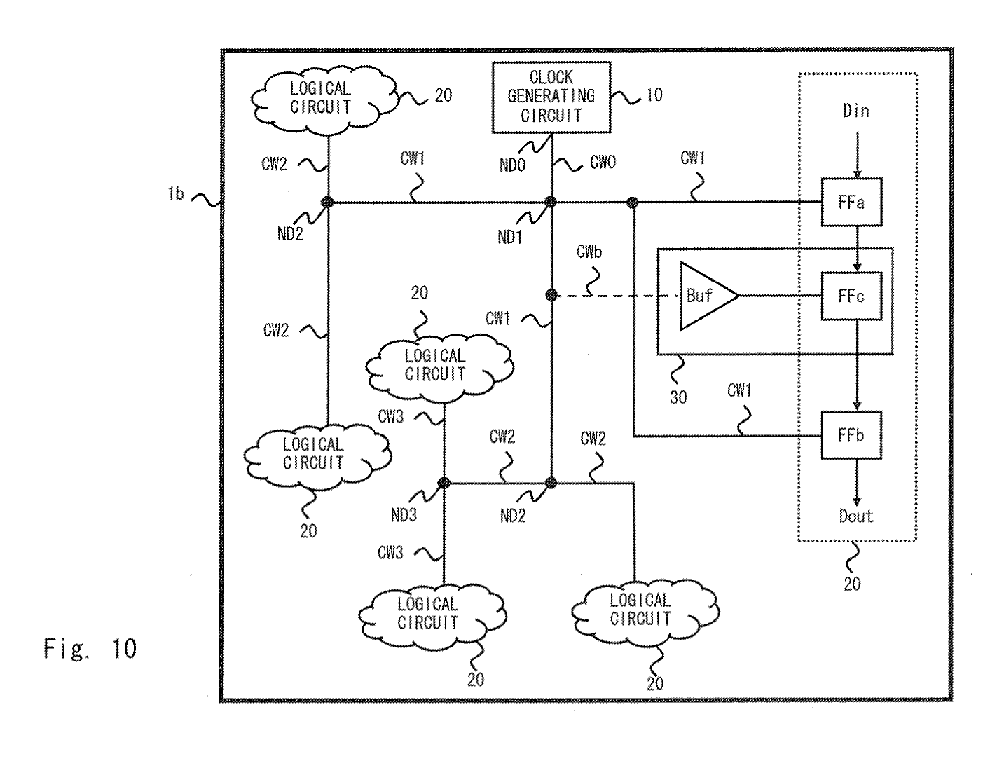

Here, an example of the block diagram of a semiconductor device 1b in which the additional supply element is determined through the processes of the above steps S33 to S36 is shown in FIG. 10. As shown in FIG. 10, the flip-flop circuits FFa and FFb included in the logical circuit 20 are supplied with the clock signal from the clock wiring line CW1 having the same number of branch stages, and further, when the additional supply element 30 is connected to the clock wiring line CW1, the flip-flop circuit FFc included in the additional supply element 30 is inserted between the existing flip-flop circuits FFa and FFb.

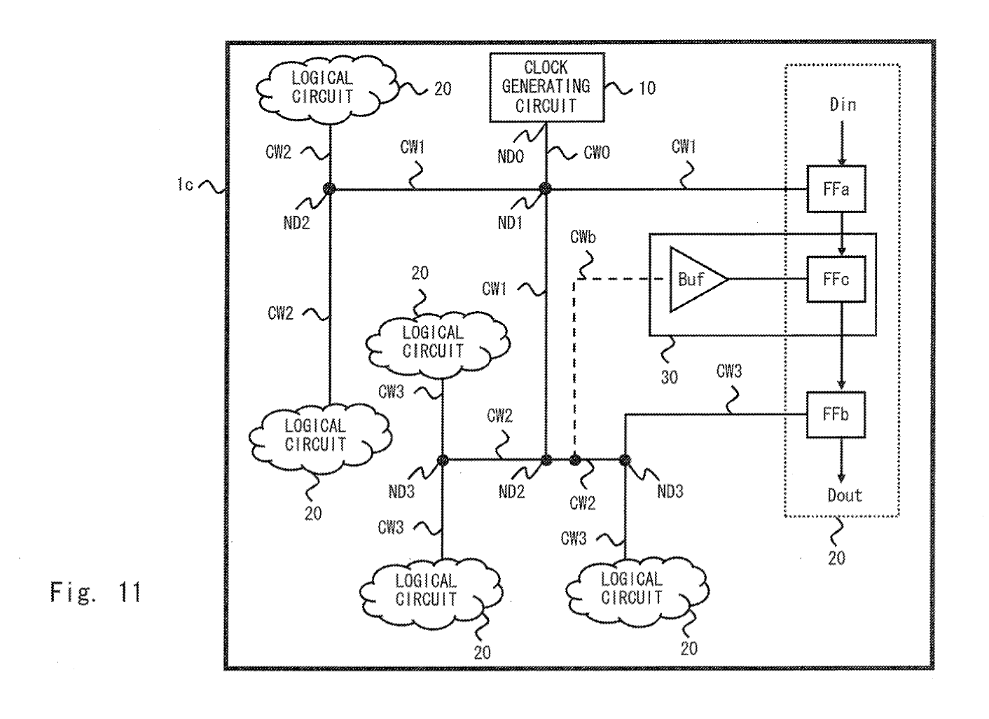

Additionally, an example of a block diagram of a semiconductor device 1c in which the additional supply element is determined through the processes of the above steps S33 to S38 is shown in FIG. 11. As shown in FIG. 11, the flip-flop circuits FFa and FFb included in the logical circuit 20 are respectively supplied with the clock signal from the clock wiring lines CW1 and CW3 having different number of branch stages, and further, when the additional supply element 30 is not connected to the clock wiring line CW1 and the clock wiring line CW3, a different clock wiring line from the clock wiring line CW1 and the clock wiring line CW3 is searched. In the example shown in FIG. 11 at this time, since the additional supply element 30 is provided to the clock wiring line CW2, the flip-flop circuit FFc included in the additional supply element 30, which connected to the clock wiring line CW2, is inserted between the existing flip-flop circuits FFa and FFb.

From the above-mentioned explanation, in the design support device 200 according to the third exemplary embodiment, when performing the circuit correction using the additional supply element 30, it is possible to determine the additional supply element after identifying the correcting element by calculation. This eliminates the necessity for the designer to search for the additional supply element to use, thereby reducing the design period. Moreover, in the design support device 200, the additional supply elements used for the circuit correction are selected in an order of connection to the clock wiring line having the number of branch stages close to the clock wiring line which supplies the clock signal to the correcting element. Therefore, it is possible to lower the possibility that circuit operation will he unstable from the additional supply element used for circuit correction.

Note that the present invention is not limited to the above exemplary embodiments, but may be modified as appropriate without departing from the scope. For example, the way to use the additional supply element 30 in the circuit correction can be selected by the designer. Further, in the step S37 of the circuit correction procedure shown in FIG. 9, when a plurality of the second selected wiring lines are detected, the designer may select from the plurality of selected candidate.

Furthermore, the circuit correction method explained in the first to the third exemplary embodiments can be provided as a program executed by a computer. This program can be provided by being recorded on a recording medium, and also can be provided by being transmitted via the Internet and other communication media. Further, the recording medium includes, for example, flexible disks, hard disks, magnetic disks, magneto-optical discs, CD-ROMs, DVDs, ROM cartridges, RAM memory cartridges with a battery back-up, flash memory cartridges, non-volatile RAM cartridges. Furthermore, the communication medium includes wired communication media such as telephone lines, and wireless communication media such as microwave lines.

The present application claims priority rights of and is based on Japanese Patent Application No. 2009-051880 filed on Mar. 5, 2009 in the Japanese Patent Office, the entire contents of which are hereby incorporated by reference.

### INDUSTRIAL APPLICABILITY

The present invention relates to a semiconductor device, a circuit correction method, a design support device, and a design support program, and can he especially used for a semiconductor device including the clock wiring line which distributes a clock signal to a trigger signal driving element, a circuit correction method of the semiconductor device, a design support device, and a design support program.

### REFERENCE SIGNS LIST

1, 1a to 1c SEMICONDUCTOR DEVICE
10 CLOCK GENERATING CIRCUIT
20 LOGICAL CIRCUIT
30 ADDITIONAL SUPPLY ELEMENT
40 CALCULATION DEVICE
41 INPUT DEVICE
42 DISPLAY DEVICE
50 PROGRAM MEMORY
51 ADDITIONAL SUPPLY ELEMENT CONDITIONING UNIT
51 ADDITIONAL SUPPLY ELEMENT CONDITIONING UNIT
52 BRANCH POSITION DETERMINING UNIT
53 TRIGGER WIRING CORRECTING UNIT
60 DATABASE MEMORY
61 ADDITIONAL SUPPLY ELEMENT NUMBER INFORMATION
62 ADDITIONAL SUPPLY ELEMENT CONSTRAINT INFORMATION
63 ADDITIONAL SUPPLY ELEMENT STATISTICAL INFORMATION
64 BRANCH POSITION INFORMATION
65 FIRST NETLIST FOR DESIGN EVALUATION
66 SECOND NETLIST FOR DESIGN EVALUATION
70 PROGRAM MEMORY
71 CORRECTING ELEMENT SEARCHING UNIT
72 CLOCK SOURCE ANALYSIS UNIT
73 ADDITION TARGET DETERMINING UNIT
74 CIRCUIT CORRECTING UNIT
80 DATABASE MEMORY
81 NETLIST FOR RETICLES
82 NETLIST FOR CORRECTED LAYOUT
83 CORRECTING ELEMENT ANALYSIS INFORMATION
84 CLOCK SOURCE ANALYSIS INFORMATION
100 DESIGN SUPPORT DEVICE
200 DESIGN SUPPORT DEVICE
BUF BUFFER
CW0 to CW3 CLOCK WIRING LINE
CWb ADDITIONAL CLOCK WIRING LINE
FF, and FFa to FFc FLIP-FLOP CIRCUIT

1. A semiconductor device comprising:
a plurality of trigger signal driving elements that synchronize with a trigger signal and operate;
a trigger wiring line that distributes the trigger signal to the plurality of trigger signal driving elements;
an additional trigger wiring line that is provided by branching from the trigger wiring line; and
an additional supply element that is supplied with the trigger signal via the additional trigger wiring line, and separated from the plurality of trigger signal driving elements.

2. The semiconductor device according to claim 1, wherein the additional supply element is a buffer circuit in which an output terminal is not connected to other element.

3. The semiconductor device according to claim 1, wherein the additional supply element is a flip-flop circuit including the output terminal and an input terminal are loop-connected, and the clock signal is input to the trigger signal input terminal via the additional clock wiring line.

4. The semiconductor device according to claim 1, wherein the additional supply element comprises the flip-flop circuit including the output terminal and the output terminal being loop-connected, and a buffer circuit that supplies the clock signal input via the additional clock wiring line to the trigger signal input terminal of the flip-flop circuit.

5. A circuit correction method of a semiconductor device comprising a trigger wiring line that transmits a trigger signal, and a plurality of trigger signal driving elements that operate according to the trigger signal, the circuit correction method comprising:
previously providing an additional supply element that is connected to the trigger wiring line via an additional trigger wiring line and also not connected to any of the plurality of trigger driving elements;
searching for a correcting element that is to be corrected among the plurality of trigger signal driving elements; and
connecting the correcting element and the additional supply element.

6. The circuit correction method according to claim 5, wherein the additional supply element is determined where in the trigger wiring line the additional supply element is connected according to a previously specified constraint.

7. The circuit correction method according to claim 5, wherein the trigger wiring line includes a plurality of branch wiring lines, and the constraint is specified for each of the branch wiring line.

8. The circuit correction method according to claim 5, wherein the constraint is a skew value of the trigger signal.

9. A design support device that, in a design process of a semiconductor device, places an additional supply element and an additional trigger wiring line for connecting the additional supply element and a trigger wiring line to the trigger wiring line for distributing a trigger signal to a trigger signal driving element, the design support device comprising:
an additional supply element conditioning means that generates additional supply element statistical information indicating a number of the additional supply element for each of the constraint according to a number of the additional supply element and the constraint of the additional supply element;
a branch position determining means that extracts information of the trigger wiring line from a first netlist describing connection information of a circuit including the plurality of trigger signal driving elements, and determines a position to place the additional supply element included in the additional supply element statistical information according to an extracted number of branch stage of the trigger wiring line, and outputs branch position information describing position information of the additional supply element; and
a trigger wiring correction means that adds the connection information of the additional supply element and the additional trigger wiring line to the first netlist according to the branch position information and generates a second netlist.

10. The design support device according to claim 9, wherein the branch position determining means searches for the number of branch stage of the trigger wiring line that satisfies the constraint included in the statistical information, and determines a position of the trigger wiring line corresponding to the searched number of branch stage as the additional supply element and the additional trigger wiring line.

11. The design support device according to claim 9, wherein the trigger wiring line includes a plurality of branch wiring lines and the constraint is specified for each of the branch wiring line.

12. The design support device according to claim 9, wherein the constraint is a skew value of the trigger signal.

13. A design support device that connects an additional supply element connected to a trigger signal driving element for operating according to a trigger signal included in a first netlist generated after completing a layout via a trigger wiring line and an additional trigger wiring line for transmitting the trigger signal, and also not connected to the trigger signal driving element, the design support device comprising:
a correcting element searching means that searches for the trigger signal driving element positioned to both ends of an element adding node, which is to be corrected, from the first netlist, and registers the searched trigger signal driving element as a correcting element;
a clock supplier analysis means that analyzes a number of branch stage of the trigger wiring line connected to the correcting element, and outputs clock supplier analysis information indicating the analyzed number of branch stage;
an addition target determining means that searches for the additional supply element connected to the trigger wiring line including the number of branch stage matching or close to the trigger wiring line for supplying the trigger signal to the correcting element according to the clock supplier analysis information, and determines the searched additional supply element as the additional supply element to be added; and
a circuit correction means that generates a second netlist, in which the additional supply element determined by the addition target determining means is connected to the trigger signal driving element.

14. The design support device according to claim 13, wherein the addition target determining means preferentially selects the additional supply element, which is connected to the trigger wiring line including the number of branch stage close to the trigger wiring line for supplying the trigger signal to the correcting element as an addition target.

15. The design support device according to claim 13, wherein the trigger wiring line includes a plurality of branch wiring lines and a constraint is specified for each of the branch wiring line.

16. The design support device according to claim 13, wherein the constraint is a skew value of the trigger signal.

17. A recording medium storing a design support system that is executed by a calculation device and in a design process of a semiconductor device, places an additional supply element and an additional trigger wiring line for connecting the additional supply element and a trigger wiring line to the trigger wiring line for distributing a trigger signal to a trigger signal driving element, the design support program comprising:
an additional supply element conditioning means that reads additional supply element number information indicating a number of the additional supply element and additional supply element constraint information indicating a constraint of the additional supply element from a memory and stores additional supply element statistical information indicating the number of additional supply element for each of the constraint to the memory;
a branching position determining means that reads a first netlist describing connection information of a circuit including the plurality of trigger signal driving elements from the memory, extracts information of the trigger wiring line from the first netlist, determines a position to place the additional supply element included in the additional supply element statistical information according to an extracted number of branch stage of the trigger wiring line, and stores branch position information describing position information of the additional supply element to the memory; and
a trigger wiring correction means that adds the connection information of the additional supply element and the additional trigger wiring line to the first netlist according to the branch position information read from the memory, generates a second netlist, and stores the second netlist to the memory.

18. A recording medium storing the design support program according to claim 17, wherein the branch position determining means searches for the number of branch stage of the trigger wiring line that satisfies the constraint included in the statistical information, and determines a position of the trigger wiring line corresponding to the searched number of branch stage as the additional supply element and the additional trigger wiring line.

19. A recording medium storing the design support program according to claim 17, wherein the trigger wiring line includes a plurality of branch wiring lines and the constraint is specified for each of the branch wiring line.

20. A recording medium storing the design support program according to one of claim 17, wherein the constraint is a skew value of the trigger signal.

21. A recording medium storing a design support program that is executed by a design support program calculation device, and connects an additional supply element connected to a trigger signal driving element for operating according to a trigger signal included in a first netlist generated after completing a layout via a trigger wiring line and an additional trigger wiring line for transmitting the trigger signal, and also not connected to the trigger signal driving element, the design support program comprising:
a correcting element searching means that reads the first netlist from a memory, searches for the trigger signal driving element positioned to both ends of an element adding node, which is to be corrected, from the first netlist, and stores correcting element analysis information indicating the searched trigger signal driving element to the memory;
a clock supplier analysis means that reads the first netlist and the correcting element analysis information form the memory, analyzes a number of branch stage of the trigger wiring line connected to the correcting element, and stores clock supplier analysis information indicating the analyzed number of branch stage;
an addition target determining means that reads the clock supplier analysis information from the memory, searches for the additional supply element connected to the trigger wiring line including the number of branch stage matching or close to the trigger wiring line for supplying the trigger signal to the correcting element, and determines the searched additional supply element as the additional supply element to be added; and
a circuit correction means that generates a second netlist, in which the additional supply element determined by the addition target determining means is connected to the trigger signal driving element, and stores the second netlist to the memory.

22. A recording medium storing the design support program according to claim 21, wherein the addition target determining means preferentially selects the additional supply element, which is connected to the trigger wiring line including the number of branch stage close to the trigger wiring line for supplying the trigger signal to the correcting element as an addition target.

23. A recording medium storing the design support program according to claim 21, wherein the trigger wiring line includes a plurality of branch wiring lines and a constraint is specified for each of the branch wiring line:

24. A recording medium storing the design support program according to one of claim 21, wherein the constraint is a skew value of a trigger signal.
